(19) United States
(12) Patent Application Publication
(10) Pub. No.: US 2013/0015421 A1
(43) Pub. Date: Jan. 17, 2013

(54) PHASE-CHANGE RANDOM ACCESS MEMORY DEVICE AND METHOD OF MANUFACTURING THE SAME

(71) Applicants: Joon Seop SIM, Ichon-si (KR); Jae Hyun Son, Ichon-si (KR); Dae Woong Lee, Ichon-si (KR); Young Hoon Oh, Ichon-si (KR)

(72) Inventors: Joon Seop SIM, Ichon-si (KR); Jae Hyun Son, Ichon-si (KR); Dae Woong Lee, Ichon-si (KR); Young Hoon Oh, Ichon-si (KR)

(21) Appl. No.: 13/339,691

(22) Filed: Dec. 29, 2011

(30) Foreign Application Priority Data
Jul. 13, 2011 (KR) 10-2011-0069323

(51) Int. Cl. H01L 47/00; H01L 21/02

(52) U.S. Cl. 257/2; 438/382; 257/E47.001; 257/E21.004

(57) ABSTRACT

A phase change random access memory (PCRAM) device and method of manufacturing the same are provided. The PCRAM includes bottom electrode contacts formed on a semiconductor substrate that includes a lower structure, phase-change material patterns in contact with the bottom electrode contacts, respectively, and heat insulating units formed between the phase-change material patterns.

### CROSS-REFERENCES TO RELATED APPLICATION

The present application claims priority under 35 U.S.C. 119(a) to Korean application number 10-2011-0069323, filed on Jul. 13, 2011, in the Korean Patent Office, which is incorporated by reference in its entirety as if set forth in full.

### BACKGROUND

1. Technical Field

The present invention relates to a semiconductor device, and more particularly, to a phase-change random access memory (PCRAM) device and a method of manufacturing the same.

2. Related Art

Phase-change random access memory (PCRAM) devices change a phase-change layer interposed between a top electrode and a bottom electrode in a crystalline state or an amorphous state through current flow between the top electrode and the bottom electrode. Information stored in a cell is read using a difference between a resistance of the phase-change layer in the crystalline state and resistance of the phase-change layer in the amorphous state.

The PCRAM devices may use a chalcogenide layer as the phase-change material. The chalcogenide layer denotes a compound of chalcogen elements such as sulfur (S), selenium (Se), and Tellurium (Te). As a chalcogenide material, germanium-antimony-tellurium (GST, Ge₂Sb₂Te₅) or silver-indium-antimony-tellurium (Ag—In—Sb—Te) may be used. Generally, a solid material may be divided into a crystalline material such as a metal, where atoms are regularly arranged, and an amorphous material such as glass, where atoms are irregularly arranged. The chalcogenide material has a transition characteristic between the crystalline state and the amorphous state. Thus, the chalcogenide material is referred to as a phase-change material. When the chalcogenide material is heated and reaches a melting point, an atomic arrangement is in disorder and the chalcogenide material is melted. After the chalcogenide material is melted, when the melted material is rapidly cooled, a regular arrangement of the atoms is in order and the material becomes in an amorphous state (a reset state, logical data ‘1’). When the material in the amorphous state is heated again, the disordered atomic arrangement is reordered and the material is in a crystalline state (set state, logical data ‘0’) again.

FIG. 1 is a cross-sectional view illustrating a conventional PCRAM device.

Referring to FIG. 1, the conventional PCRAM includes a switching device 103, a bottom electrode 105, a phase-change material pattern 107, and a top electrode 109 formed on a semiconductor substrate 101 in a vertical structure.

The phase-change material pattern 107 has an array type, and a distance between adjacent cells is narrow as a design rule of a device is scaled down to a 60 nm grade. Under the 60 nm grade, when Joule heating for phase-change is generated for the selected cell A, the heat intended for selected cell A is transferred to surrounding cells B and C as well. By transferring the heat to the surrounding cells B and C, an unintended cell may be phase-changed. More specifically, when resetting the selected cell, the heat applied to the selected cell is propagated to the surroundings cells, and thus, temperatures of the surrounding cells are increased. When logical data ‘1’ is recorded in the surrounding cell, a crystalline state of the phase-change material pattern 107 is changed by the heat propagated from the heat generated for the selected cell, and thus, the data of the surrounding cell may be changed from logical data ‘1’ to logical data ‘0’. The changing of the logical data in a surrounding cell may be called disturbance.

A heating temperature of above 600° C. is applied to perform a reset operation, but a set operation is performed at a heating temperature of about 200° C.

A method of forming a bottom electrode in a dash type has been suggested to prevent thermal interference. However, vulnerability still remains.

### SUMMARY

According to one aspect of an exemplary embodiment, a phase-change random access memory (PCRAM) device includes bottom electrode contacts formed on a semiconductor substrate that includes a lower structure; phase-change material patterns in contact with the bottom electrode contacts, respectively; and heat insulating units formed between the phase-change material patterns.

According to another aspect of an exemplary embodiment, a method of manufacturing a PCRAM device includes forming a phase-change material layer on a semiconductor substrate including bottom electrode contacts insulated by a first interlayer insulating layer; forming phase-change material patterns by patterning the phase-change material layer to be in electrical contact with the bottom electrode contacts, respectively, wherein the forming of the phase-change material patterns includes etching the first interlayer insulating layer between the phase-change material patterns; and forming a second interlayer insulating layer on the semiconductor substrate including the phase-change material patterns and the etched first interlayer insulating layer.

These and other features, aspects, and embodiments are described below in the section entitled “DESCRIPTION OF EXEMPLARY EMBODIMENT”.

### BRIEF DESCRIPTION OF THE DRAWINGS

The above and other aspects, features and other advantages of the subject matter of the present disclosure will be more clearly understood from the following detailed description taken in conjunction with the accompanying drawings, in which:

FIG. 1 is a cross-sectional view illustrating a conventional phase-change random access memory (PCRAM) device;

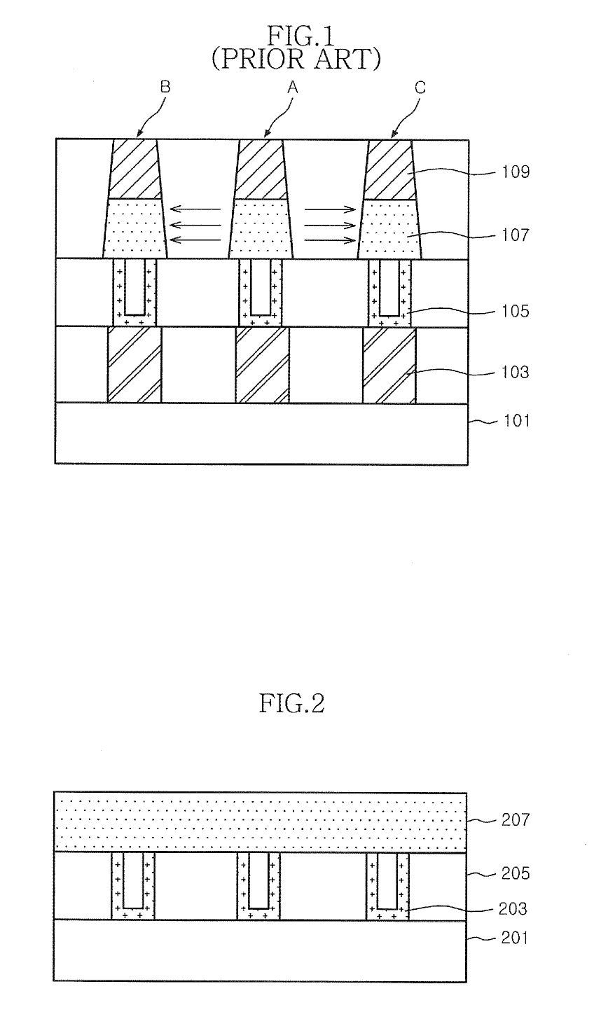

FIGS. 2 to 5 are cross-sectional views illustrating a method of manufacturing a PCRAM device according to an exemplary embodiment of the present invention;

FIG. 6 is a layout diagram illustrating a PCRAM according to another exemplary embodiment of the present invention; and

FIG. 7 is a view illustrating a degree of heat propagated to an adjacent cell in a write operation of a PCRAM device.

### DESCRIPTION OF EXEMPLARY EMBODIMENT

Hereinafter, exemplary embodiments will be described in greater detail with reference to the accompanying drawings.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other or substrate, or intervening layers may also be present.

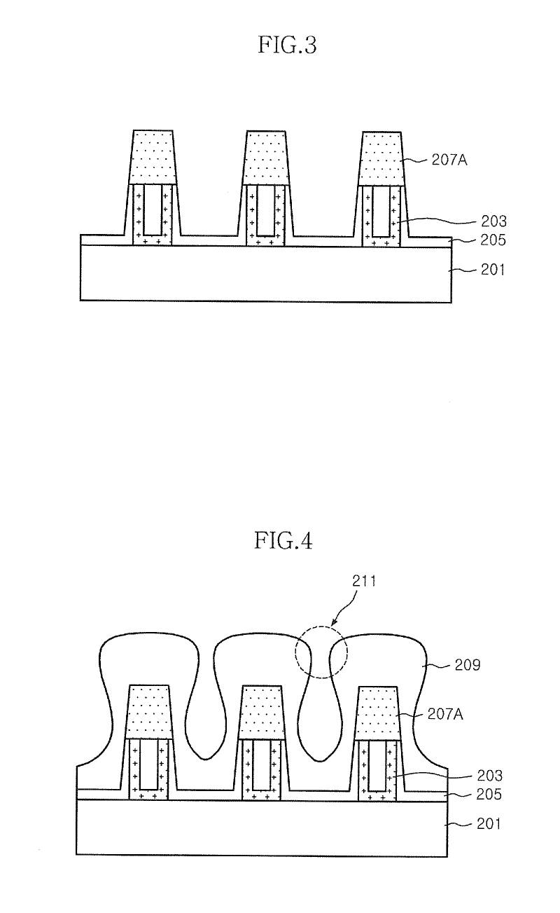

FIGS. 2 to 5 are cross-sectional views illustrating a method of manufacturing a phase-change random access memory (PCRAM) device according to an exemplary embodiment of the inventive concept.

First, referring to FIG. 2, a bottom electrode contact 203 is formed on a semiconductor substrate 201 where a lower structure is formed. For example, the lower structure may include a switching device, a word line, and the like. The bottom electrode contact 203 is insulated by a first interlayer insulating layer 205 which includes, for example, a nitride layer. Subsequently, a phase-change material layer 207 is formed on an entire structure of the semiconductor substrate 201 including the bottom electrode contact 203 and the first interlayer insulating layer 205.

Referring to FIG. 3, an etching process is performed to form a phase-change material pattern 207A. When the phase-change material layer 207 is etched, the first interlayer insulating layer 205 may be used as an etch stop layer. Alternatively, the first interlayer insulating layer 205 may be etched to a designated depth. Therefore, an aspect ratio of a space between the phase-change material patterns 207A is increased.

Referring to FIG. 4, a second interlayer insulating layer 209 is formed on an entire structure of the semiconductor substrate including the phase-change material pattern 207A and the etched first interlayer insulating layer 205. The second interlayer insulating layer 209 may include a material having a poor gap-fill property. For example, the second interlayer insulating layer 209 may be formed of a silicon oxide layer (SiO₂) using a high density plasma (HDP) deposition method.

When the second interlayer insulating layer 209 is formed, since the aspect ratio of the space between the phase-change material patterns 207A has been increased, an overhang 211 is caused. The overhang 211 causes a hole to be buried within the second interlayer insulating layer 209, more specifically, a void in the second interlayer insulating layer 209 between the phase-change material patterns 207A. FIG. 5 illustrates an embodiment where the void occurs.

As shown in FIG. 5, the void is formed between the phase-change material patterns 207A after the second interlayer insulating layer 209 is formed.

The second interlayer insulating layer, for example, a HDP SiO₂ layer, has a thermal conductivity of about 1.4 W/mK. The first interlayer insulating layer, for example, a Si₃N₄ formed by a plasma-enhanced chemical vapor deposition (PECVD) method, has a thermal conductivity of about 20 W/mK. However, when the void 213 is filled with air, the void 213 has the very low thermal conductivity of about 0.024 W/mK.

Therefore, in an etching process of forming the phase-change material pattern 207A in the exemplary embodiment, when the first interlayer insulating layer 205 is etched to increase the aspect ratio of the space between the phase-change material patterns 207A and the second interlayer insulating layer 209 is formed to intentionally form the void 213, heat transfer between the phase-change material patterns 207A may be minimized. Thus, the void 213 may be referred to as a heat insulating unit. The void 213, or more specifically, the heat insulating unit may be maintained in a vacuum state, or dry air or nitrogen may be placed within the void 213, or more specifically, the heat insulating unit.

In addition, the void 213 allows the heat generated in the phase-change material pattern 207A not to be spread to the surrounding cell, but to be propagated to a top electrode or the bottom electrode. When the PCRAM device operates, the heat loss can be minimized. Therefore, when the PCRAM device operates by the same current amount as a current amount applied to a conventional PCRAM device in a reset operation, the heating temperature of the phase-change material pattern 207A is increased. Therefore, the desired data can be recorded by a current amount corresponding to 60 to 70% of the current amount applied to the conventional PCRAM device, thereby minimizing power consumption compared to the conventional PCRAM device.

In the PCRAM device of the exemplary embodiment, the phase-change material patterns are fabricated by patterning the phase-change material layer in a word line direction as well as in a bit line direction. Thus, a void is also caused in the bit line direction.

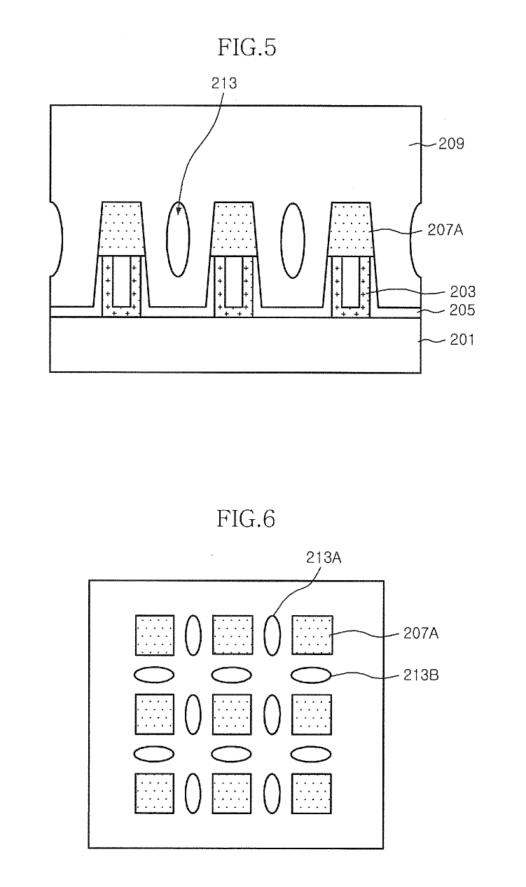

FIG. 6 is a layout diagram of the PCRAM device according to another exemplary embodiment of the present invention.

FIG. 6 illustrates that a void 213A occurs in the word line direction and a void 213B occurs in the bit line direction.

The phase-change pattern 207A is insulated from adjacent phase-change material patterns 207A in the x-axis and y-axis directions by the interlayer insulating layers including the voids 213A and 213B.

Thus, the disturbance due to a thermal interference between adjacent cells may be removed, and reliability of the PCRAM device may be ensured.

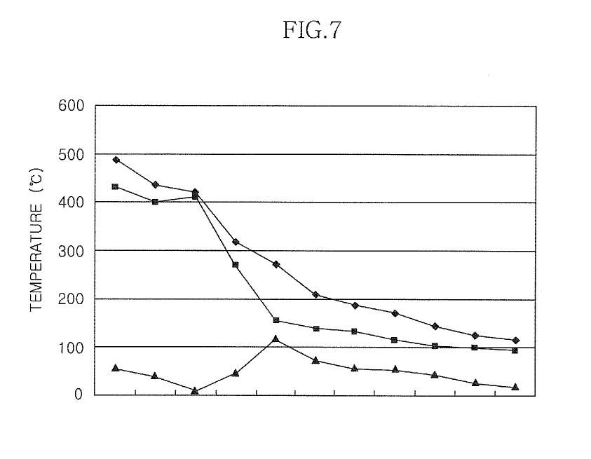

FIG. 7 is a view illustrating a degree of heat propagation to an adjacent cell in a write operation of the PCRAM device.

FIG. 7 illustrates an effect of heat propagated to an adjacent cell in a recording operation on a specific cell, which is indicated by the symbol ‘♦’, in the conventional PCRAM device, which does not include the void formed between the phase-change material patterns, an effect on heat propagated to an adjacent cell, which is indicated by the symbol ‘▪’, in the PCRAM device of the exemplary embodiment of the present invention, which includes the void formed between the phase-change material patterns, and a temperature difference between the heat effect in the conventional PCRAM device and the heat effect in the PCRAM device of the exemplary embodiment, which is indicated by the symbol ‘▴’.

As shown in FIG. 7, the heat effect of the PCRAM device of the exemplary embodiment of the present invention is improved compared to the existing PCRAM device, and the heat effect is reduced at a temperature of 100° C. to the maximum.

As described above, the PCRAM device according to the exemplary embodiment of the present invention includes the heat insulating unit between the phase-change material patterns. The heat insulating unit may contain dry air or nitrogen or be in a vacuum state.

Thermal conductivity of the heat insulating unit is considerably low compared to an insulating layer (HDP SiO₂ layer) between the phase-change material patterns or the insulating layer (PECVD Si₃N₄ layer) between the bottom electrode contacts, and thus the void serves as the heat insulating unit, thereby improving the disturbance between adjacent cells.

The amount of heat lost can be improved by forming the heat insulating unit, and thus, data can be recorded in a cell with a relatively small current amount, thereby lowering a total power consumption of the PCRAM device.

While certain embodiments have been described above, it will be understood that the embodiments described are by way of example only. Accordingly, the devices and methods described herein should not be limited based on the described embodiments. Rather, the systems and methods described herein should only be limited in light of the claims that follow when taken in conjunction with the above description and accompanying drawings.

What is claimed is:

1. A phase-change random access memory (PCRAM) device, comprising:
bottom electrode contacts formed on a semiconductor substrate that includes a lower structure;
phase-change material patterns in contact with the bottom electrode contacts, respectively; and
heat insulating units formed between the phase-change material patterns.

2. The PCRAM device of claim 1, wherein the phase-change material patterns are patterned in an island type in a word line direction and a bit line direction.

3. The PCRAM device of claim 1, wherein the heat insulating units include a void.

4. The PCRAM device of claim 1, wherein the heat insulating units are filled with dry air.

5. The PCRAM of claim 1, wherein the heat insulating units are filled with nitrogen.

6. The PCRAM device of claim 1, wherein the heating insulating units are in a vacuum state.

7. The PCRAM device of claim 1, further comprising an interlayer insulating layer formed between the phase-change material patterns to insulate the phase-change material patterns,
wherein the heat insulating units are formed within the interlayer insulating layer between the phase-change material patterns.

8. The PCRAM device of claim 1, wherein the lower structure of the substrate includes a switching device, a word line, or a bit line.

9. A method of manufacturing a phase-change random access memory (PCRAM) device, comprising:
forming a phase-change material layer on a semiconductor substrate including bottom electrode contacts insulated by a first interlayer insulating layer;
forming phase-change material patterns by patterning the phase-change material layer to be in electrical contact with the bottom electrode contacts, respectively, wherein the forming of the phase-change material patterns includes etching the first interlayer insulating layer between the phase-change material patterns; and
forming a second interlayer insulating layer on the semiconductor substrate including the phase-change material patterns and the etched first interlayer insulating layer.

10. The method of claim 9, wherein the forming of the phase-change material patterns includes etching the phase-change material layer in a word line direction and a bit line direction.

11. The method of claim 9, wherein the forming of the second interlayer insulating layer includes causing voids between the phase-change material patterns.

12. The method of claim 11, further comprising filling dry air within the voids.

13. The method of claim 11, further comprising filling nitrogen within the voids.

14. The method of claim 11, further comprising performing a vacuum treatment within the voids.

15. The method of claim 10, wherein the forming of the second interlayer insulating layer includes causing voids between the phase-change material patterns.

16. The method of claim 15, further comprising filling dry air within the voids.

17. The method of claim 15, further comprising filling nitrogen within the voids.

18. The method of claim 15, further comprising performing a vacuum treatment within the voids.

19. The method of claim 9, wherein the second interlayer insulating layer includes a material having a poor gap-fill property.

20. The method of claim 19, wherein the second interlayer insulating layer is formed of a silicon oxide layer (SiO₂) using a high density plasma (HDP) deposition method.
